(19) United States
(12) Patent Application Publication
(10) Pub. No.: US 2017/0352709 A1
(43) Pub. Date: Dec. 7, 2017

(54) ARCHITECTURE FOR VERY HIGH RESOLUTION AMOLED DISPLAY

(71) Applicant: Universal Display Corporation, Ewing, NJ (US)

(72) Inventors: Michael Hack, Princeton, NJ (US); Michael Stuart Weaver, Princeton, NJ (US); Nicholas J. Thompson, Trenton, NJ (US); Julia J. Brown, Yardley, PA (US); Ruiqing Ma, Morristown, NJ (US)

(21) Appl. No.: 15/172,888

(22) Filed: Jun. 3, 2016

(51) Int. Cl. H01L 27/32; H01L 51/52; H01L 51/56

(52) U.S. Cl. CPC H01L 27/3209; H01L 51/56; H01L 51/5275; H01L 51/5268; H01L 27/3213; H01L 51/5206; H01L 51/5234; H01L 27/322; H01L 27/3244

(57) ABSTRACT

Full-color pixel arrangements for use in displays and other devices, and devices including the same, are provided. The pixel arrangement includes a patterned electrode layer including multiple electrodes, a patterned emissive layer disposed over the electrode layer, a blanket organic emissive layer disposed over the patterned emissive layer, a second electrode layer disposed between the organic emissive layers, and a third electrode layer disposed over the second blanket organic emissive layer. Electrodes within each of the electrode layers are individually addressable.

### PARTIES TO A JOINT RESEARCH AGREEMENT

The claimed invention was made by, on behalf of, and/or in connection with one or more of the following parties to a joint university corporation research agreement: Regents of the University of Michigan, Princeton University. University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to arrangements suitable for providing high-resolution displays and devices such as organic light emitting diodes and other devices, including the same, and techniques for the fabrication thereof.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art.

One example of a green emissive molecule is tris(2-phenylpyridine) iridium, denoted Ir(ppy)₃, which has the following structure:

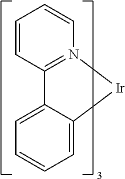

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

According to an embodiment, a full-color pixel arrangement, such as for use in a display, is provided, which includes a first electrode layer having a plurality of first electrodes, a patterned first organic emissive layer disposed over at least a portion of the first plurality of electrodes, a blanket second organic emissive layer disposed over the first organic emissive layer, a second electrode layer disposed between the first and second organic emissive layers, and a third electrode layer disposed over the second organic emissive layer. Electrodes within each of the first, second, and third electrode layers may be addressable via an electrical connection external to the arrangement. Each of the first electrodes may be independently addressable relative to the other first electrodes and/or the other electrodes in the arrangement. Each of the first and second organic emissive layers may be independently addressable. The arrangement may include organic emissive layers of exactly two colors. A first color altering layer may be disposed in a stack with a first region of the first organic emissive layer. Alternatively or in addition, a second color altering layer disposed in a stack with a second region of the first organic emissive layer, which is distinct from the first region of the first organic emissive layer. The patterned first organic emissive layer may define a plurality of sub-pixels. Each of the sub-pixels may have a separate backplane circuit, or they may have a common backplane circuit. Overall, the arrangement may include less than one backplane circuit per sub-pixel in the arrangement. A first of the sub-pixels may a first optical path length, and a second sub-pixel may have a second optical path length that is different than the first optical path length. The second electrode layer may be transparent, or may have an absorption of not more than 30% in the 450-700 nm range. The arrangement may include at least one blue-emitting organic emissive layer and/or at least one yellow-emitting organic emissive layer. The first organic emissive layer may include a yellow-emitting emissive material, and/or the second organic emissive layer may include a blue-emitting emissive material. A deep blue color altering layer may be disposed in a stack with the second organic emissive layer and not with the first organic emissive layer. The arrangement may include sub-pixels of at least four colors.

An outcoupling component may be optically coupled to at least a portion of the arrangement, and disposed in a stack with at least one of the first plurality of electrodes. A patterned third organic emissive layer may be disposed over at least a portion of the first plurality of electrodes, which includes an emissive material having a peak wavelength of a different color than a peak wavelength of the patterned first organic emissive layer, and which is not disposed over the patterned first organic emissive layer

In an embodiment a device is provided that includes a full-color pixel arrangement as disclosed herein. The device may include a flat panel display, a computer monitor, a medical monitor, a television, a billboard, a light for interior or exterior illumination and/or signaling, a heads-up display, a fully or partially transparent display, a flexible display, a laser printer, a telephone, a cell phone, a tablet, a phablet, a personal digital assistant (PDA), a laptop computer, a digital camera, a camcorder, a viewfinder, a micro-display, a 3-D display, a virtual reality or augmented reality display, a vehicle, a large area wall, a theater or stadium screen, a sign, or any combination thereof.

In an embodiment, a method of fabricating a full-color pixel arrangement is provided that includes disposing a first electrode layer comprising a plurality of first electrodes over a substrate, fabricating a patterned first organic emissive layer disposed over at least a portion of the first plurality of electrodes, fabricating a blanket second organic emissive layer disposed over the first organic emissive layer, fabricating a second electrode layer disposed between the first and second organic emissive layers, and fabricating a third electrode layer disposed over the second organic emissive layer. Electrodes within each of the first, second, and third electrode layers may be addressable via an electrical connection external to the arrangement. The method further may include fabricating a patterned third organic emissive layer disposed over at least a portion of the first plurality of electrodes. The patterned third organic emissive layer may include an emissive material having a peak wavelength of a different color than a peak wavelength of the patterned first organic emissive layer, and may not be disposed over the patterned first organic emissive layer. Devices resulting from the methods disclosed herein may have the structure, composition, and arrangement of components and features of any of the pixel arrangements and other devices as disclosed herein.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an example fabrication sequence according to embodiments of the invention.

FIG. 4 shows an example sub-pixel architecture which may reduce cross-talk of one blue sub-pixel to its neighbor according to embodiments of the invention.

FIG. 5 shows an example bottom emitting device according to embodiments of the invention.

FIG. 6 shows a top emitting device according to embodiments of the invention.

FIG. 7 shows a bottom emitting device according to embodiments of the invention.

FIG. 8 shows a top emitting device according to embodiments of the invention.

FIG. 9 shows an “RGB1B2” implementation according to embodiments of the invention.

FIG. 10 shows an example process using red/green masking with no color filters, showing sub-pixels for two pixels according to embodiments of the invention.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-1”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

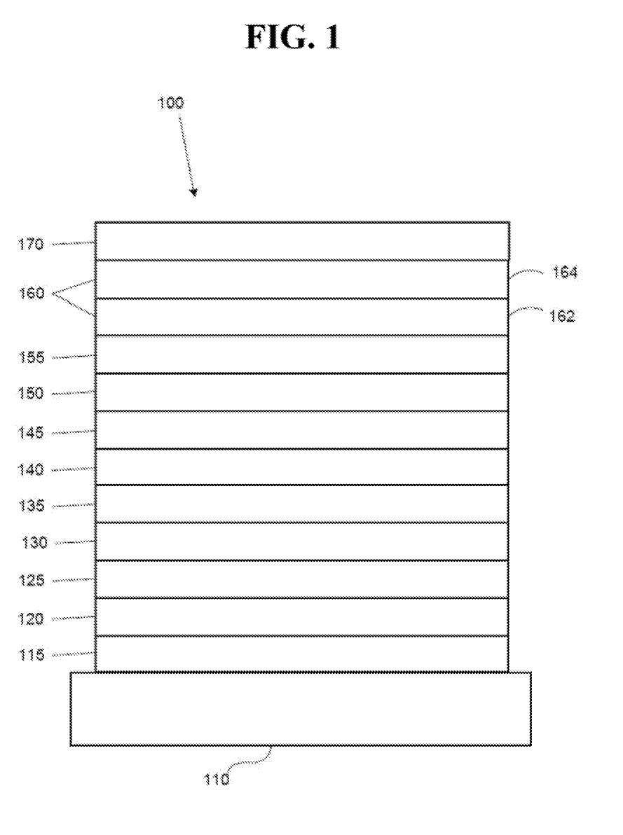

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

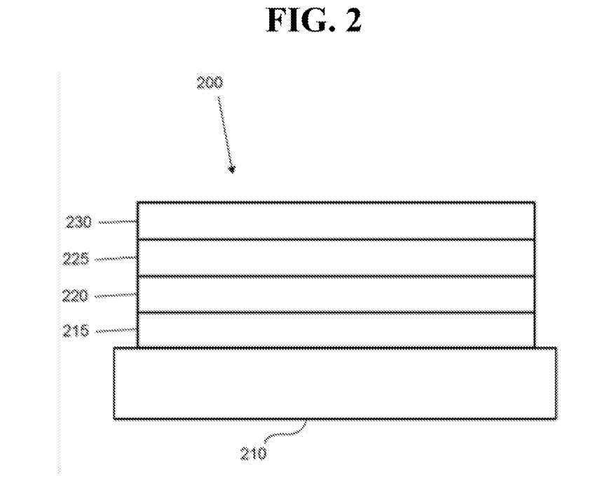

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve outcoupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, cell phones, tablets, phablets, personal digital assistants (PDAs), laptop computers, digital cameras, camcorders, viewfinders, micro-displays, 3-D displays, virtual reality or augmented reality displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to +80 C.

There is an increasing need for very high resolution OLED displays—for example for virtual reality applications. To achieve 3D and virtual reality effects it is often desirable to have very high resolution, often greater than 1,000 dpi or 1,500 dpi. Conventional techniques to achieve relatively high resolution often use a “white plus color filter” approach to avoid OLED patterning. Such techniques have several drawbacks, such as reduced OLED lifetime, especially of the blue sub-pixels, difficulties implementing a top emission white stack, and an inability to deliver high color gamut because current color filter technology does not prevent a deep saturated green emitter, for example, from bleeding into a blue sub-pixel, causing cross talk. Such techniques also have key performance disadvantages relative to RGB side-by-side arrangements. First, color filters may reduce the light output, thereby reducing the blue lifetime as the blue fill factor is effectively low, so increased luminance is needed to compensate. Second, it typically is difficult to optimize a white top emission cavity for all three colors, so performance is lower than RGB side by side. Third, blue color filters typically cannot completely cut out deep green, so only yellow green emitters can be used, lowering the efficiency of any deep green sub-pixels.

U.S. Patent Publication Nos. 2014/0203244, 2014/0209888, 2014/0327709, 2015/183954, and 2015/0340410, and U.S. patent application Ser. No. 14/605,748, the disclosures of which are incorporated by reference in their entirety, discuss using only 2 organic depositions, such as yellow and blue, to make a full color display, and employing green and red color filters to make a four color display. In embodiments disclosed herein, similar concepts are applied but a blue OLED layer may be stacked on top of a yellow OLED layer. Both colors may be driven independently. In some configurations, only the yellow OLED may patterned, as the human eye has only low spatial resolution to blue. However, such techniques are not limited to the use of only two organic depositions.

U.S. Pat. Nos. 8,827,488 and 9,231,227 relate to having a blue sub-pixel in a different plane relative to red and green sub-pixels. However, such arrangements and techniques generally do not provide arrangements as disclosed herein, such as having only two OLED depositions with only one emissive layer masking step. These configurations also generally use a middle electrode as a common electrode, so that the three electrodes of the OLED arrangement are not separately addressable.

Embodiments disclosed herein provide architectures to enable very high OLED display resolution while maintaining the performance of RGB side by side displays. Embodiments of the present disclosure also provide OLED frontplane architectures which can be achieved by, for example stacking blue OLEDs on yellow OLEDs, using only one masking step at half the display resolution. Such an approach can be combined with other techniques to enable a high resolution backplane to drive the front plane. In some configurations, a central electrode layer includes one or more electrodes that are individually addressable, so both OLEDs (e.g., yellow and blue) can be driven independently.

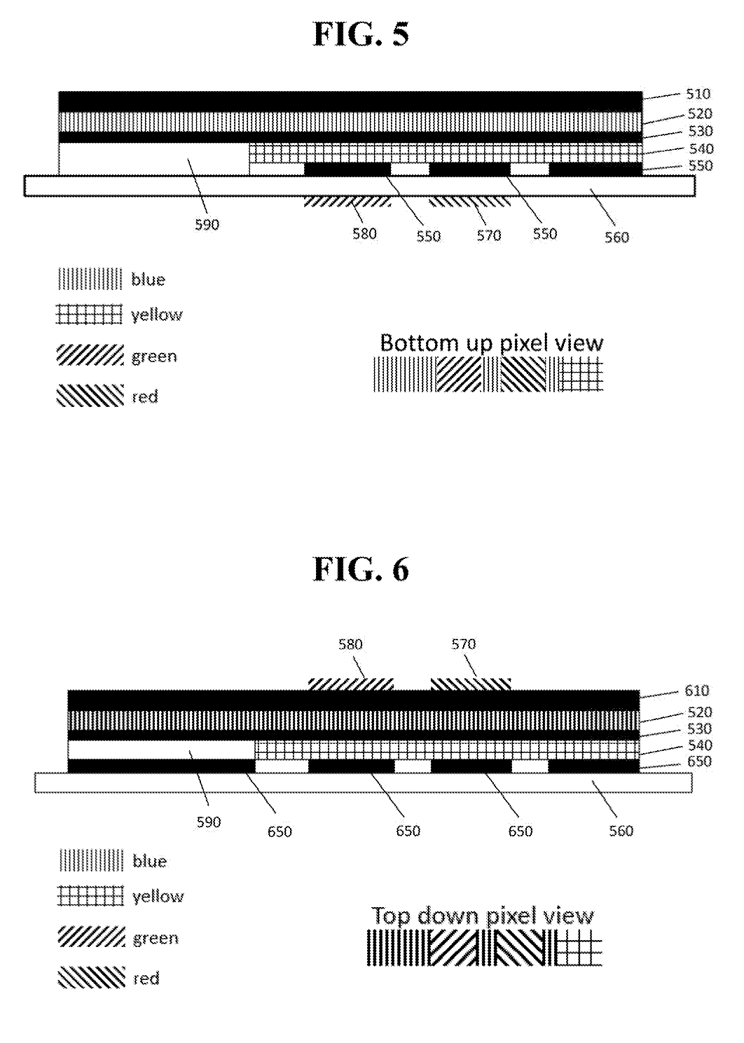

More generally, embodiments disclosed herein may provide a full-color pixel arrangement. Referring to FIG. 5, an arrangement as disclosed herein may include a first electrode layer 550 that includes multiple electrodes. A patterned organic emissive layer, such as the yellow emissive layer 540 shown in FIG. 5, may be disposed over the first electrode layer 550. A blanket layer of a second organic emissive layer 520 may be disposed over the organic emissive layer 540, and a middle electrode layer 530 disposed between the organic emissive layers 520, 540. The middle electrode layer 530 may be a blanket layer, or it may include a plurality of separate electrodes, all of which may be individually addressable. A third electrode 510 may be disposed over the organic emissive layer 520. Notably, electrodes within each of the electrode layers 510, 530, 550 may be individually addressable, i.e., each electrode may be addressed via an electrical connection that extends externally from the arrangement. Specifically, each of the individual electrodes in the electrode layer 550 may be addressable independently of each of the other electrodes in the layer 550. As shown and described in further detail herein, each of the electrode layers in arrangements disclosed herein may include a highly reflective material, i.e., may be a highly reflective electrode, or it may be transparent.

As described in further detail herein, such an arrangement may include, but it not limited to, organic emissive layers of only two colors. An organic layer that emits a particular color as disclosed herein may include one or multiple emitters, i.e., emissive materials within the layer, although generally the layer as a whole will emit only a single color. That is, each emissive layer within the arrangement may emit, when activated, only one of two colors, even in configurations in which the layer includes multiple emitters. For example, the example arrangement shown in FIG. 5 includes only blue and yellow emissive layers 520, 540, respectively. Although the arrangement includes color altering layers 570, 580, such layers are not considered emissive layers as disclosed herein because they do not generate those colors when activated by placing a voltage across the layers. Rather, the color altering layers 570, 580, such as color filters, merely alter the wavelength of incident light that passes through the layers; they do not generate any light themselves as with the emissive layers 520, 540. Such alteration may include the absorption of an initial incident color of light and re-emission of a different color of light, such as in the case of a down-converting color altering layer.

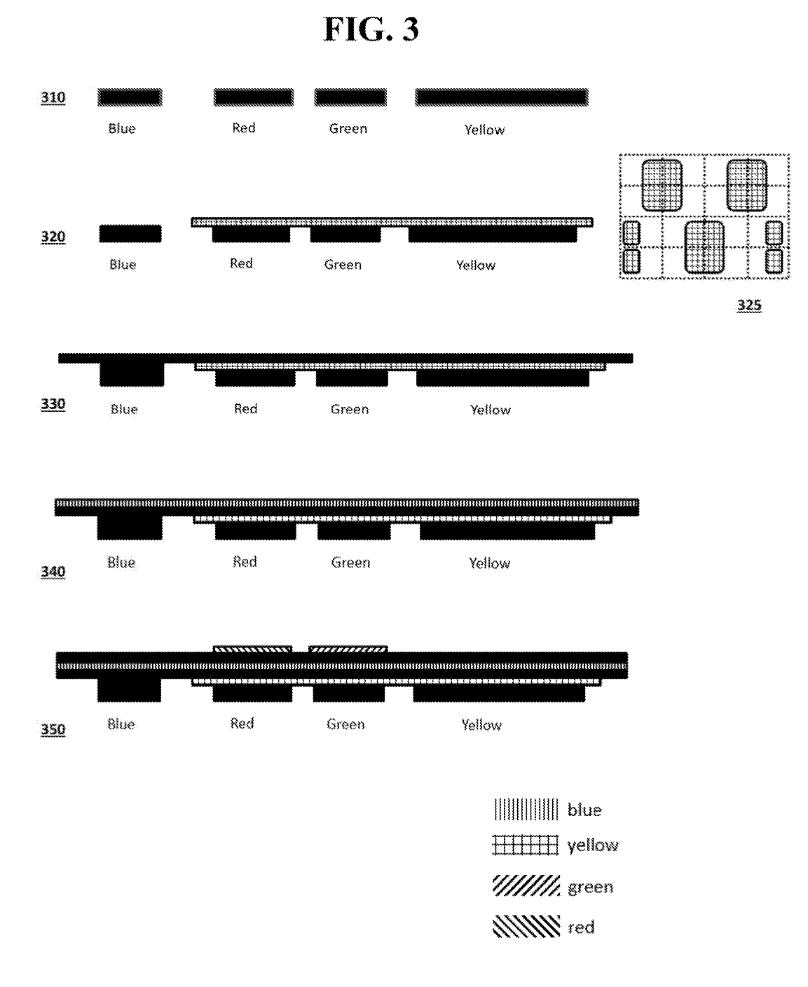

FIG. 3 shows an example process sequence to implement an architecture as disclosed herein. In the illustrated example four sub-pixels are fabricated (red, green, yellow and blue), although more than four colors could be employed. At 310 a patterned anode layer including the individual sub-pixel anodes is fabricated. As shown at 310, each sub-pixel may have a separate anode connection that provides external control of the sub-pixel. The color labels shown in 310 indicate the eventual color that will be provided by the associated sub-pixel. The particular arrangement of electrodes is illustrative, and other arrangements may be used. Each anode connection may connected to a separate backplane circuit, or a common backplane circuit could be used and multiplexed using the power supply lines, as disclosed in U.S. patent application Ser. No. ______ (Docket No. UDC-1086US), filed herewith.

At 320 a yellow emissive layer is deposited through a shadow mask. For example, four pixels at a time may be deposited, such as using a layout as described in U.S. Patent Publication No. 2015/183954 and shown in the inset to FIG. 3. Alternatively or in addition, a maskless printing process such as OVJP may be used to deposit a patterned yellow emissive layer. Because the yellow emissive layer will be used to produce yellow, red, and green sub-pixels, one, two or three (or more) emitters may be used in the yellow emissive layer. That is, the emissive layer may include a material or a mixture of materials that includes one, two, three, or more emitter materials. For example, green, red, and yellow emitters may be disposed in the same emissive layer or in separate emissive layers, which together make up the “yellow” emissive layer as disclosed herein. The yellow OLED may be a single OLED or a stacked OLED to improve lifetime at a given luminance and/or efficiency of the OLED, for example by doubling the OLED voltage relative to the backplane TFT voltage. In some embodiments this emissive layer may be patterned such that a deposition area may be disposed within multiple adjacent pixels, such as shown in the schematic top view of an example deposition 325. Other arrangements may be used, for example, as disclosed in U.S. Patent Publication No. 2015/183954.

At 330, a conductive transparent middle electrode may be deposited as a blanket layer. For example, the middle electrode may be, or include, ITO, IZO, thin film metal, carbon nanotubes, metallic nanowires, or combinations thereof. The blue anode may connect directly to the middle electrode, whereas this middle electrode will serve as a cathode for the yellow, red, and green OLED sub-pixels. At 340, a blanket blue OLED layer is deposited over the middle electrode. Red and green color filters may be incorporated into the device at 350 to produce red and green sub-pixels from the yellow deposition. The blue layer also may be stacked to improve lifetime and system efficiency.

Because the human eye typically is less sensitive to the resolution of blue light relative to red, green, and especially yellow light, it may be acceptable for the blue resolution of a device as disclosed herein to be only half or less of the other primary colors. In selecting a material or combination of materials for the middle electrode, it may be desirable for the conductivity of the electrode to be sufficiently low that it maintains a constant voltage plane throughout each pixel, taking into account that it serves as a cathode to the red, green and yellow sub-pixels. For a 1,000 dpi display with a 25 μm×25 μm pixel driven at 1 mA/cm², the pixel current is 0.01 μA. To maintain a voltage rise on the central electrode of less than 1 mV so to not cause image artifacts, the sheet resistance of the middle electrode should be less than 100,000 ohms, i.e, on the order of 100,000 ohms per square.

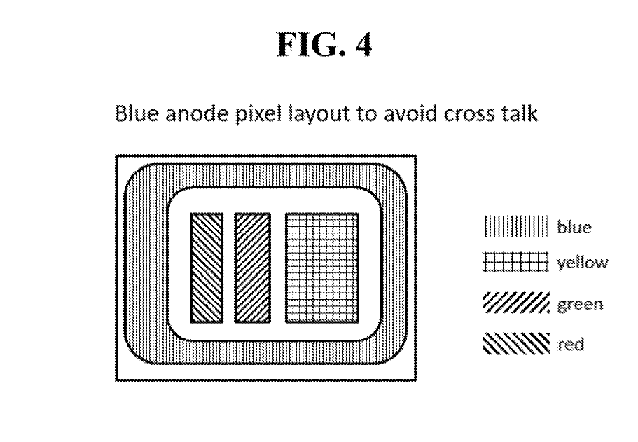

Because the blue OLED is unpatterned, it also may be desirable to prevent cross-talk from one blue pixel to neighboring pixels. As disclosed herein, each pixel may have a dedicated anode to drive the blue sub-pixel. This contact may ensure the correct voltage at each middle electrode to deliver the correct blue luminance at each pixel. As a result, the maximum bleed of blue from any given pixel can only extend as far as the nearest neighbors of the blue pixel. Because of the relative lack of sensitivity of the human eye to blue resolution, embodiments disclosed herein typically will not result in sufficient cross-talk to be perceptible. If there is undue cross-talk, a different sub-pixel anode layout may be used, an example of which is shown in FIG. 4. In this configuration, each blue-sub pixel anode is a ring shape, while the blue OLED stack itself is continuous. As a result all the blue light from the region inside the ring is only controlled by the blue anode of that pixel, with no interference from neighboring pixels.

As described in further detail herein, in a bottom emission configuration a blanket top cathode may be a metal, and the anode connections may be transparent. In this case the red and green color filters may be patterned under the OLED stack, under or over the transparent anodes.

US Patent Publication No. 2015/0340410 describes techniques to optimize individual red, green, and/or yellow sub-pixels in a top emission architecture using anode patterning techniques to adjust the cavity length to maximize the red and green output, and/or to tune the color of light emitted by the sub-pixel. In a top emission structure as disclosed herein, the anodes may be reflective, and light may be emitted through the blanket cathode.

Using deposition and etching techniques, one or more layers of material may be disposed between a reflective layer and an electrode, to change the thickness of the electrode stack in different regions of the electrode. For example, layers of silicon dioxide and silicon nitride may be fabricated on top of a metal reflector layer, under an ITO anode. To optimize such an architecture in a top emission configuration, the yellow and blue OLED stacks may be optimized for green and blue emission respectively. Optical path length may then be added to the red and yellow anodes to optimize their cavity lengths. Examples of such configurations are shown in FIGS. 5-8.

FIG. 5 shows an example of a bottom emission structure as disclosed herein. A highly reflective electrode 510 is disposed over a blanket blue layer 520. A yellow emissive layer 540 is disposed between a weakly reflective and/or transparent middle electrode 530. An electrode layer 550 may include multiple electrodes to form the green, red, and yellow subpixels, using green and red color altering layers 580, 570, respectively as shown. An optical spacer or filler 590 may be patterned on the substrate 560, outside of the yellow stack of each pixel. The optical filler may be, for example, an insulator with the same effective optical path length as the yellow emissive material, or it may be a material such as ITO and the yellow emissive material, thus requiring no mask during deposition of the yellow emissive material. In such a configuration the optical filler region still may be unaddressed, because there is no via from the optical filler to the TFT. Such patterning may be performed, for example, prior to organic evaporation. FIG. 6 shows an analogous structure to FIG. 5 for a top emission structure, in which the electrode layer 650 is highly reflective and the electrode 610 is weakly reflective and/or transparent. The weakly reflective electrode 610 may include, for example, TCO that is IZO- or ITO-like.

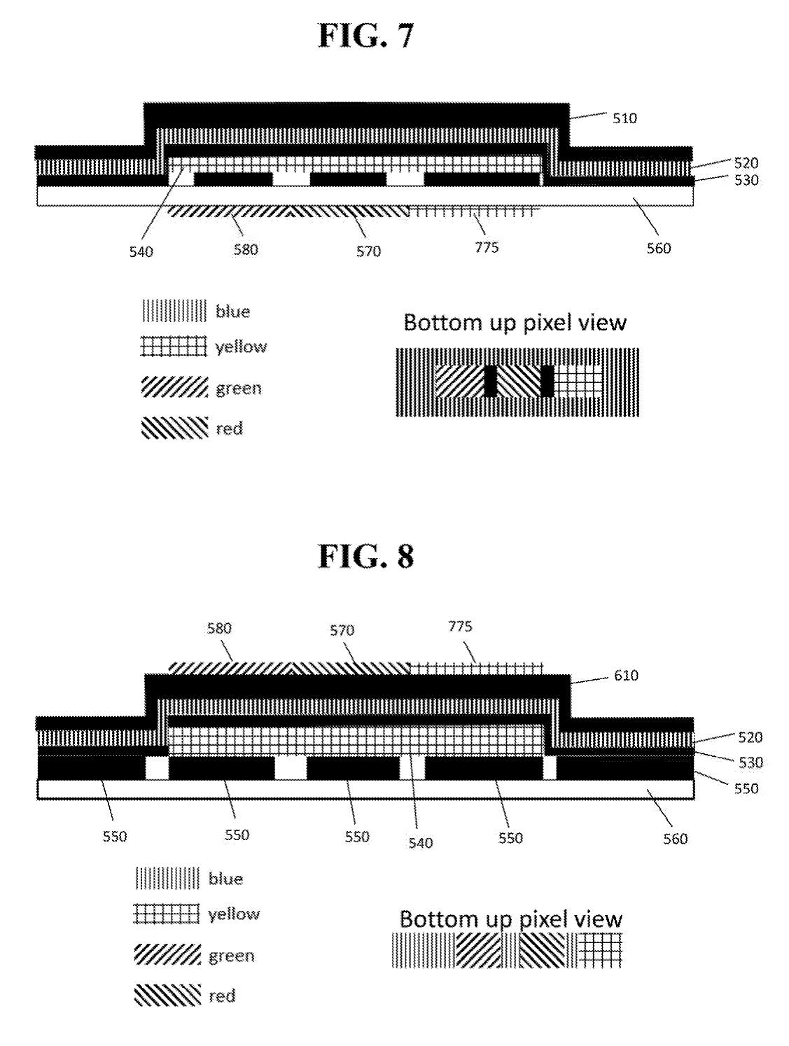

FIGS. 7 and 8 show bottom and top emission device structures without an optical filler, which enable blue micro-cavity device characteristics. A device as shown in FIG. 7 also may include a yellow color altering layer such as a color filter 775, to remove blue emission from the yellow sub-pixel when the blue sub-pixel is energized. A device as shown in FIG. 7 may provide a bottom emission microcavity (BEMC) blue sub-pixel, while also having Lambertian yellow sub-pixel without the use of an additional optical filler. Similarly, a device as shown in FIG. 8 may provide a top emission microcavity (TEMC) blue sub-pixel and a Lambertian yellow sub-pixel, without requiring an additional optical filler.

To avoid cross-talk of the blue sub-pixel affecting light output from the yellow, red, or green sub-pixels in the same pixel, various drive schemes may be used. For example, the blue sub-pixel may be driven for 50% of the time, and then the yellow-based sub-pixels, i.e., in the illustrated examples, those sub-pixels based on emission by the emissive layer closest to the substrate, for the remainder of the time. This 50:50 ratio in time may be adjusted to balance sub-pixel lifetimes, such as by decreasing the relative time that the blue sub-pixel is driven if the blue sub-pixel is expected to have a lower lifetime. In practice such a scheme may be implemented by switching power rails at either the scan line addressing time or the frame time. Using frame time selection during the first portion of each frame time, the voltages of the green, yellow, and red anodes may be set to the middle electrode potential to ensure no emission. The voltage drop across the blue device from the common middle electrode to the upper cathode may provide a desired blue luminance for each pixel. In the second “yellow” portion of each frame time, the upper cathode may be turned off and set to the same potential as the common middle electrode to ensure no blue emission. The blue anode connection is then the effective cathode to the yellow, green, and red devices. Such an architecture may be used to achieve very high resolution, and for small devices (e.g. less than 10″), relatively high frame rates (e.g. 120 Hz) should be readily achievable.

It is possible that when the blue stack is energized in any given pixel, and the yellow stack is off, that blue light will be absorbed by the yellow EML under the blue pixel and then the absorbed blue light will be re-emitted as yellow or green light depending, on the specifics of the emitters used to produce yellow light. Initial results suggest that this effect is approximately 0.1%, i.e., that the yellow emission of a layer energized by absorption of blue light from the upper stack would be approximately 0.1% of the intensity of the emitted blue light.

Such cross-talk may be further reduced by reverse biasing the yellow pixel during operation of the blue upper pixel. It also may be further reduced by using a lower doping concentration of the emitters, such as 0.2-10% by volume, in the yellow pixel, as they often may represent a large part of the parasitic absorption within the pixel. As another example, a fine metal mask may be used to deposit a blue absorbing film that is transmissive of yellow light over the yellow portion of each pixel. This absorption film may be disposed between two conductive films, so the middle electrode would be include a transparent conductor/blue filter/transparent conductor arrangement, with the blue filter deposited only over the yellow EML region so that it does not prevent electrical contact between the blue anode and the blue OLED device. Because the fill factor of the yellow pixel is less than the blue pixel, the visual impact of this effect will be further reduced from the 0.1% level. Overall such an effect may appear to shift the blue sub-pixel slightly towards the white point, but in a spatially uniform manner and in a way that depends on the grey level of the blue sub-pixel. This may have a very slight impact on the effective color of the deep blue sub-pixel. For example, assuming a (0.143, 0.043) native blue sub-pixel with an additional 0.1% yellow, the deep blue is shifted to only (0.144, 0.044), which will have a marginal visual impact. Further, even at an additional 1% yellow, the blue would only shift to (0.145, 0.046).

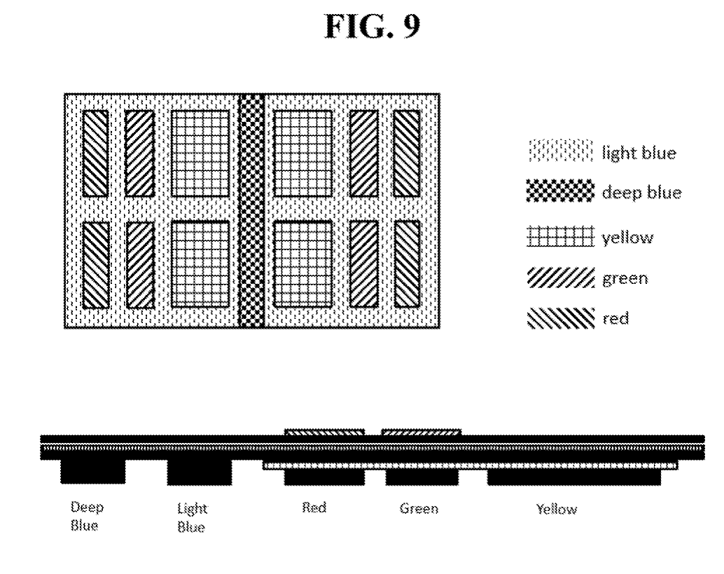

The architectures described and shown in FIGS. 5-8 may be combined a “RGB1B2” arrangement, such as disclosed in US Patent Publication No. 2015/183954. In such an arrangement a dark blue sub-pixel may be shared amongst 4 pixels. The dark blue sub-pixel may be provided, for example, by placing a color filter over a region of the light blue pixel. An example of such an arrangement is shown in FIG. 9.

In some embodiments, outcoupling features may be applied to a high resolution display arrangement as previously described. These outcoupling features may include micro-lens, scattering layers, and/or other outcoupling structures. Some example structures that may be applied to the embodiments disclosed herein are described in U.S. patent application Ser. No. ______ (Docket No. UDC-1086), filed herewith. To make such outcoupling effective for displays, it may be desirable to minimize the distance between the emissive layer and the outcoupling feature.

Because a display as disclosed herein may use a yellow/blue configuration, a colored lens may be a suitable approach since the arrangement may already incorporate one or more color filters. In such an approach, a colored lens may be placed on each sub-pixel for outcoupling. Assuming circular sub-pixels, the distance between emission layer and the lens base t should be:

t<\sqrt{nₗₑₙₛ²−1}*(r+R)=\sqrt{nₗₑₙₛ²−1}*(2r+d)

where nₗₑₙₛ, r, R, and d represent the refractive index of the micro-lens, the radius of emission sub-pixel, the radius of the lens, and the difference between r and R, respectively. For a resolution equivalent to a current smartphone and a 50″ 4k TV, t should be less than 28 μm and 89 μm, respectively.

The outcoupling structure may be applied to all display pixels. It also may be applied only to selective display pixels depending on factors such as the pixel layout, the efficiency and lifetime of each color component, and the sensitivity of human eyes or lenses of only one color could be applied to the display. However, with the improved efficiency provided by outcoupling structures, there may be decrease in contrast and pixel definition due to cross-talk. In some cases, it may be preferred to apply outcoupling features only to selected pixels or colors. For example, outcoupling structures may be applied only to the blue pixels. Because the human eye typically is less sensitive to the resolution of blue light relative to red, green, and especially yellow light, the decrease in resolution due to optical cross-talk may be less noticeable or not noticeable. At the same time, blue emission typically needs more light output and lifetime improvement relative to yellow, green, or blue emissive layers, which are improved by the use of outcoupling features. As another example of applying outcoupling features only to selective pixels, a sub-pixel arrangement and/or dimensions may prevent the application of outcoupling features to all individual subpixels, such as where certain sub-pixels are too small or too close for outcoupling features to be applied.

In some cases, it may be preferred for multiple pixels or sub-pixels to share the same outcoupling features. For example, sub-pixels may be too small for precision placement of the outcoupling features. Multiple sub-pixels may then share the same outcoupling feature. For example, a micro-lens sheet or a scattering ring may be disposed so as to cover multiple subpixels.

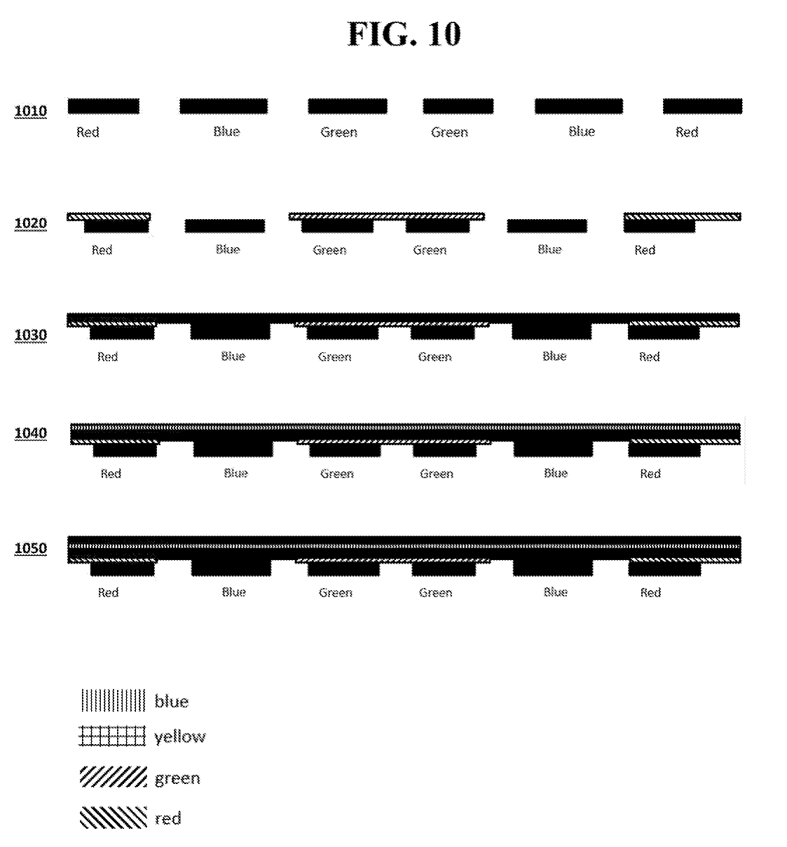

In an embodiment, separate patterned green and red depositions may be used in a first plane, and an unpatterned blue deposition may be used in a second plane. Such a configuration may avoid the need for color altering layers such as color filters. Because there are only two colors used and patterned in the first plane, the colors may be alternated, thereby allowing for two sub-pixels of the same color to be deposited at the same time using the same mask opening (e.g., in the direction of the scan line)—so the mask only needs to be half the resolution of the display. In such a configuration, the blue anode may be placed between the red and green anode connections in each pixel. One backplane may be used to control all 3 colors. Such a configuration differs from U.S. Pat. No. 9,231,227, in that the central electrode is addressable and is an anode, not common cathode, connection. For example, FIG. 10 shows such a process, using an example of sub-pixels for two adjacent pixels. At 1010, the sub-pixel anodes may be patterned for multiple pixels. At 1020, red and green emissive materials may be deposited through shadow masks, depositing four sub-pixels at a time, or using a technique such as OVJP with a bank to reduce spillover. Notably, the red and green sub-pixel pairs are alternated, with blue sub-pixels disposed between them. At 1030, a blanket middle electrode may be deposited. At 1040, a blanket blue emissive layer may be deposited over the middle electrode. A blanket electrode then may be deposited over the blue emissive layer at 1050.

As used herein, a highly reflective electrode or reflective layer refers to an electrode layer having a reflectivity greater than 80%, more preferably 90%, and more preferably 95% over the 450 to 700 nm wavelength range. Similarly, a weakly reflective or transparent electrode refers to an electrode layer having an absorption of 30% or less, more preferably 20% or less, more preferably 10% or less in the 450 to 700 nm range.

As used herein, a blanket layer refers to one in which the material that makes up the layer covers the entirety, or substantially the entirety of, the layer immediately below it, in a continuous layer. In contrast, a patterned layer is one in which the material that makes up the layer covers only a portion of the layer immediately below it and includes multiple non-continuous regions. For example, a patterned electrode layer may include several electrically-isolated electrodes deposited in the same layer of a device, which are separated by another material such as an insulator. Similarly, a blanket deposition refers to a layer or a portion of a layer that is fabricated so as to completely cover the portion of the layer immediately below the blanket deposition in a continuous area. A patterned deposition refers to a deposition that includes multiple non-continuous regions that are separated by other material or by no material. For example, an organic deposition may be considered patterned if it is placed over a specific sub-pixel or sub-pixels in each pixel, but not everywhere else within the pixel area. A deposition may refer to an entire layer of an arrangement as disclosed herein or to only a portion of a layer, typically for a sub-device such as a sub-pixel that is associated with the deposition.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

1. A full-color pixel arrangement comprising:
a first electrode layer comprising a plurality of first electrodes;
a patterned first organic emissive layer disposed over at least a portion of the first plurality of electrodes;
a blanket second organic emissive layer disposed over the first organic emissive layer, wherein the second organic emissive layer has a blue emitting emissive material;
a second electrode layer disposed between the first and second organic emissive layers; and
a third electrode layer disposed over the second organic emissive layer;
wherein electrodes within each of the first, second, and third electrode layers are addressable via an electrical connection external to the arrangement, and
wherein the full-color pixel arrangement has a deep blue color altering layer disposed in a stack with the second organic emissive layer and not with the first organic emissive layer.

2. The full-color pixel arrangement of claim 1, wherein the arrangement comprises organic emissive layers of exactly two colors.

3. The full-color pixel arrangement of claim 1, wherein each of the first electrodes is independently addressable.

4. The full-color pixel arrangement of claim 1, wherein each of the first and second organic emissive layers is independently addressable.

5. The full-color pixel arrangement of claim 1, further comprising a first color altering layer disposed in a stack with a first region of the first organic emissive layer.

6. The full-color pixel arrangement of claim 5, further comprising a second color altering layer disposed in a stack with a second region of the first organic emissive layer, distinct from the first region of the first organic emissive layer.

7. The full-color pixel arrangement of claim 1, wherein the patterned first organic emissive layer defines a plurality of sub-pixels.

8. The full-color pixel arrangement of claim 7, wherein each sub-pixel has a separate backplane circuit.

9. The full-color pixel arrangement of claim 7, wherein each sub-pixel has a common backplane circuit.

10. The full-color pixel arrangement of claim 7, wherein the arrangement comprises less than one backplane circuit per sub-pixel.

11. The full-color pixel arrangement of claim 7, wherein a first sub-pixel of the plurality of sub-pixels has a first optical path length, and a second sub-pixel of the plurality of sub-pixels has a second optical path length different than the first optical path length.

12. The full-color pixel arrangement of claim 1, wherein the second electrode layer is transparent.

13. The full-color pixel arrangement of claim 1, wherein the second electrode has an absorption of not more than 30% in the 450-700 nm range.

14. The full-color pixel arrangement of claim 1, wherein the first organic emissive layer comprises a yellow-emitting emissive material, the second organic emissive layer comprises a blue-emitting emissive material, or both.

15. (canceled)

16. (canceled)

17. The full-color pixel arrangement of claim 1, wherein the arrangement comprises sub-pixels of at least four colors.

18. (canceled)

19. The full-color pixel arrangement of claim 1, further comprising an outcoupling component optically coupled to at least a portion of the arrangement and disposed in a stack with at least one of the first plurality of electrodes.

20. The full-color pixel arrangement of claim 1, further comprising a patterned third organic emissive layer disposed over at least a portion of the first plurality of electrodes, wherein the patterned third organic emissive layer comprises an emissive material having a peak wavelength of a different color than a peak wavelength of the patterned first organic emissive layer, and wherein the patterned third organic emissive layer is not disposed over the patterned first organic emissive layer

21. A device comprising the full-color pixel arrangement of claim 1, wherein the device comprises at least one selected from the group consisting of: a flat panel display, a computer monitor, a medical monitor, a television, a billboard, a light for interior or exterior illumination and/or signaling, a heads-up display, a fully or partially transparent display, a flexible display, a laser printer, a telephone, a cell phone, a tablet, a phablet, a personal digital assistant (PDA), a laptop computer, a digital camera, a camcorder, a viewfinder, a micro-display, a 3-D display, a virtual reality or augmented reality display, a vehicle, a large area wall, a theater or stadium screen, and a sign.

22. A method of fabricating a full-color pixel arrangement comprising:
disposing a first electrode layer comprising a plurality of first electrodes over a substrate;
fabricating a patterned first organic emissive layer disposed over at least a portion of the first plurality of electrodes;
fabricating a blanket second organic emissive layer disposed over the first organic emissive layer, wherein the second organic emissive layer has a blue emitting emissive material;
fabricating a second electrode layer disposed between the first and second organic emissive layers; and
fabricating a third electrode layer disposed over the second organic emissive layer;
wherein electrodes within each of the first, second, and third electrode layers are addressable via an electrical connection external to the arrangement, and
wherein the full-color pixel arrangement has a deep blue color altering layer disposed in a stack with the second organic emissive layer and not with the first organic emissive layer.

23. (canceled)
